(19) United States
(12) Patent Application Publication
(10) Pub. No.: US 2016/0343892 A1
(43) Pub. Date: Nov. 24, 2016

(54) SOLAR CELL MODULE AND MANUFACTURING METHOD OF SAME

(71) Applicant: GIXIA GROUP CO., Zhubei (TW)

(72) Inventors: JUNG-YA HSIEH, Hsinchu (TW); SHIH-YUAN LIN, Taipei (TW); YUNG-FU LIN, Hsinchu (TW); YUAN-HSIN CHANG, Hsinchu (TW)

(21) Appl. No.: 15/012,874

(22) Filed: Feb. 2, 2016

Related U.S. Application Data
(60) Provisional application No. 62/162,832, filed on May 18, 2015.

(51) Int. Cl. H01L 31/049

(52) U.S. Cl. CPC H01L 31/049

(57) ABSTRACT

A solar cell module sequentially includes a protecting plate, a cell structure and a supporting structure. A manufacturing method of the solar cell module includes only one step of hot pressing the protecting plate, the cell structure, and the supporting structure together. This manufacturing method saves time and improves efficiency. Moreover, hot pressing does not cause serious deformation of the supporting structure even though the thermal expansion coefficients of materials are different.

### CROSS REFERENCE TO RELATED APPLICATION

This application claims priority from U.S. Provisional Patent Application Ser. No. 62/162,832, filed May 18, 2015.

### FIELD

The subject matter herein generally relates to solar cell modules and manufacturing method of the same.

### BACKGROUND

Solar cell modules are designed to absorb the sun's rays for generating electricity or heating. FIG. 1 is a side view of a conventional solar cell module 100. The solar cell module 100 sequentially includes a protecting plate 101, a cell structure 102, a back sheet 103, and a supporting structure 104. The back sheet 103 is made of plastic materials. The supporting structure 104 is made of metal. The protecting plate 101, the cell structure 102, and the back sheet 103 are bonded together by hot pressing. The back sheet 103 and the supporting structure 104 are bonded together by adhesive.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a side view of a conventional solar cell module.

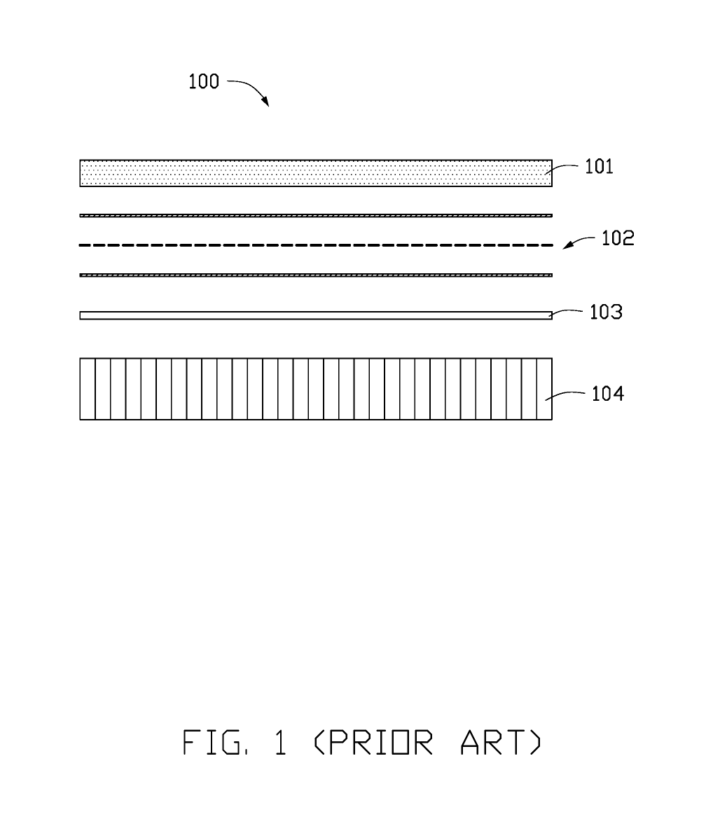

FIG. 2 is a side view of a solar cell module of an embodiment of the present disclosure.

FIG. 3 is an exploded perspective view of a supporting structure of the solar cell module of FIG. 2.

FIG. 4 is a side view of a supporting structure of a solar cell module of another embodiment of the present disclosure.

FIG. 5 is a side view of the solar cell module of FIG. 4, showing a bottom plate of the supporting structure being folded.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one.”

The term “comprising” means “including, but not necessarily limited to”; it specifically indicates open-ended inclusion or membership in a so-described combination, group, series and the like.

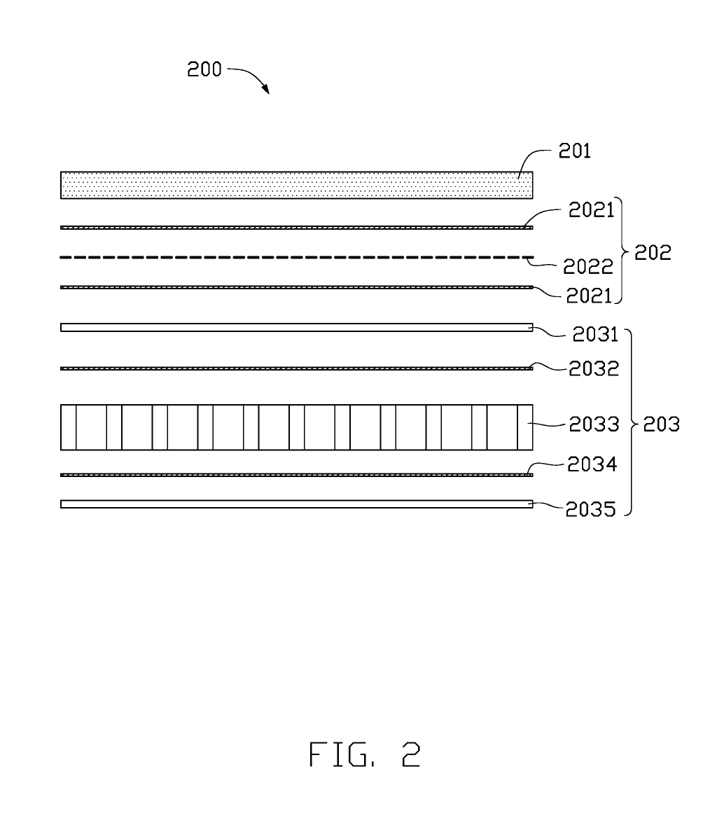

FIG. 2 shows a solar cell module 200 of an embodiment of the present disclosure. The solar cell module 200 sequentially comprises a protecting plate 201, a cell structure 202, and a supporting structure 203. The protecting plate 201, the cell structure 202, and the supporting structure 203 are bonded together by hot pressing. The protecting plate 201 is a silicone plate, which is a plate with light weight and protecting function and can be well used as a protecting plate. Preferably, the protecting plate 201 is a polymeric organosilicon compound plate such as a polydimethylsiloxane (PDMS) plate. The cell structure 202 has two ethylene-vinyl acetate (EVA) layers 2021 and a cell 2022 between the two EVA layers 2021. The EVA layers 2021 are in the form of sheets.

The protecting plate 201 has an outward surface and an inward surface. The outward surface can be coated with an ultraviolet (UV)-resistant film to extend the lifetime of the protecting plate 201. The inward surface can be coated with a cross linking agent or have microstructures formed thereon to improve the adhesion between the EVA layer 2021 and the protecting plate 201. The microstructures can assist in a vacuum suction procedure.

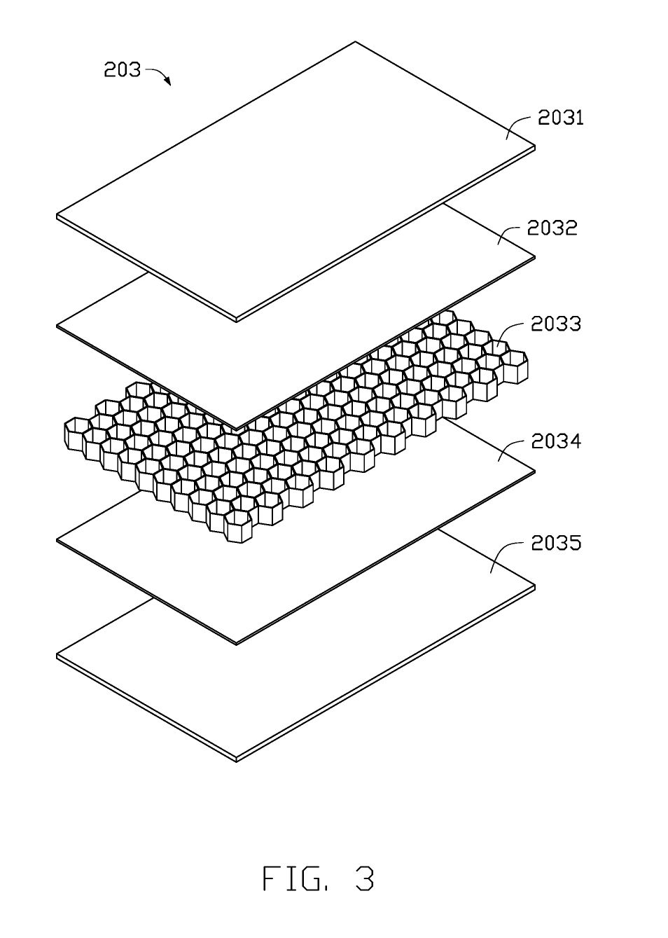

FIG. 3 shows the supporting structure 203 of the solar cell module 200 of FIG. 2. The supporting structure 203 sequentially has a top plate 2031, a top EVA layer 2032, a honeycomb core 2033, a bottom EVA layer 2034, and a bottom plate 2035. The top plate 2031 is a plastic plate. The top and bottom EVA layers 2032, 2034 are in the form of sheets. The honeycomb core 2033 is made of metal such as aluminum. The bottom plate 2035 can be a plastic plate, a metal plate, or a plate having an upper layer of metal and a lower layer of plastic.

A manufacturing method of a conventional solar cell module must include two steps, the steps of hot pressing and of adhesion. The two step method is time consuming. Moreover, deformation of a back sheet and of a supporting structure can occur due to different thermal expansion coefficients of the back sheet and of the supporting structure and adhesion between the back sheet and the supporting structure. A manufacturing method of the solar cell module 200 of the present disclosure comprises only one step of hot pressing together the protecting plate 201, the cell structure 202, and the supporting structure 203. This manufacturing method saves time and improves efficiency. Moreover, hot pressing does not cause serious deformation of the supporting structure 203 even though the thermal expansion coefficients of materials are different.

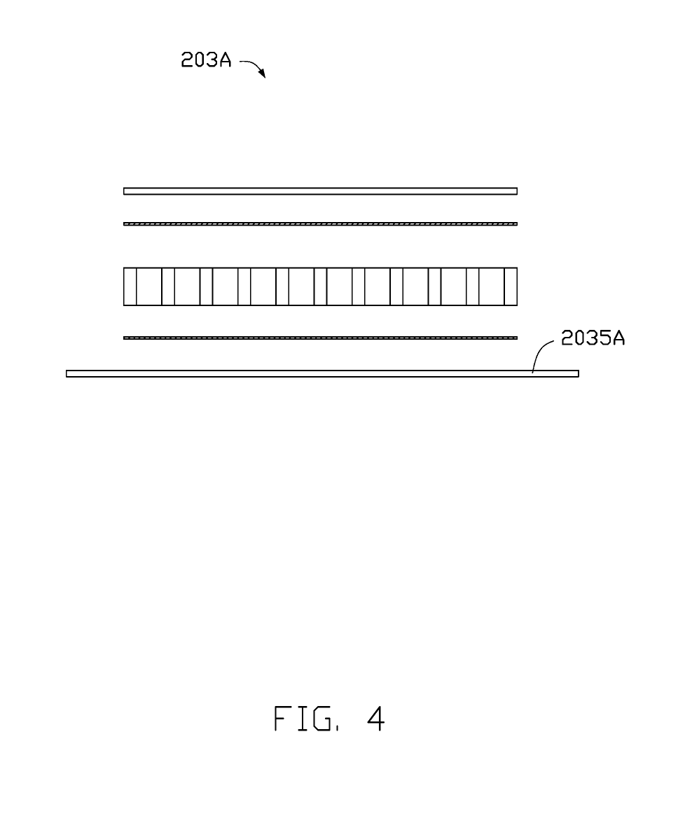

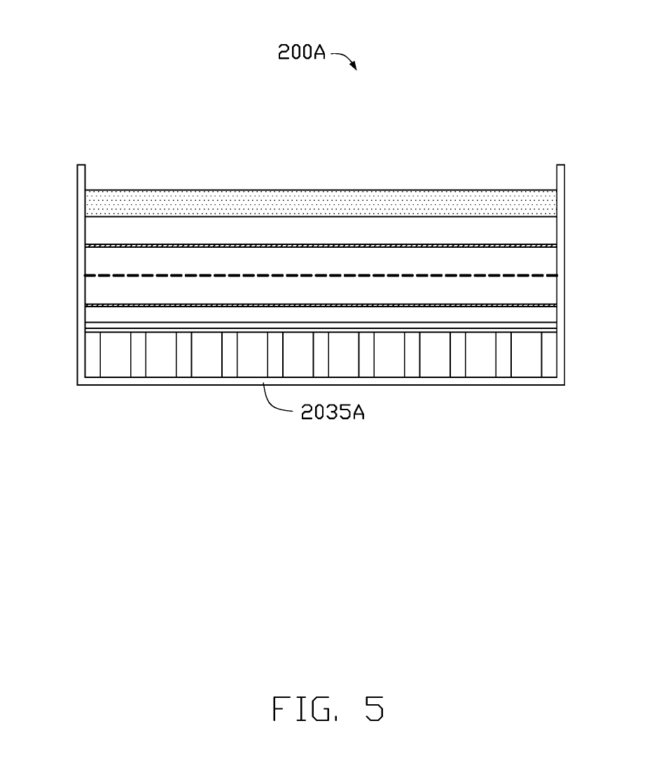

FIG. 4 shows a supporting structure 203A of a solar cell module 200A of another embodiment of the present disclosure. The bottom plate 2035A of the supporting structure 203A is a metal plate or a plate having an upper layer of metal and a lower layer of plastic. FIG. 5 is a side view of the solar cell module 200A of FIG. 4. The bottom plate 2035A is folded to form a frame.

The embodiments shown and described above are only examples. Many details are often found in the art such as the other features of a solar cell module and manufacturing method of same. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A solar cell module sequentially comprising:
a protecting plate being a silicone plate, a cell structure and a supporting structure bonded together by hot pressing.

2. The solar cell module of the claim 1, wherein the supporting structure sequentially has a top plate, a top EVA layer, a honeycomb core, a bottom EVA layer and a bottom plate.

3. The solar cell module of the claim 2, wherein the top and bottom EVA layers are in the form of sheets.

4. The solar cell module of the claim 2, wherein the top plate is a plastic plate.

5. The solar cell module of the claim 2, wherein the honeycomb core is made of metal.

6. The solar cell module of the claim 5, wherein the honeycomb core is made of aluminum.

7. The solar cell module of the claim 1, wherein the protecting plate is a polymeric organosilicon compound plate.

8. The solar cell module of the claim 7, wherein the protecting plate is a PDMS plate.

9. The solar cell module of the claim 1, wherein the protecting plate has an outward surface coated with a UV-resistant film.

10. The solar cell module of the claim 1, wherein the protecting plate has an inward surface coated with a cross linking agent.

11. The solar cell module of the claim 1, wherein the protecting plate has an inward surface formed with microstructures.

12. The solar cell module of the claim 2, wherein the bottom plate is a plastic plate.

13. The solar cell module of the claim 2, wherein the bottom plate is a plate having an upper metal layer and a lower plastics layer.

14. The solar cell module of the claim 13, wherein the bottom plate is folded to form a frame.

15. The solar cell module of the claim 14, wherein the cell structure has two EVA layers and a cell between the two EVA layers.

16. The solar cell module of the claim 2, wherein the bottom plate is a metal plate.

17. The solar cell module of the claim 16, wherein the bottom plate is folded to form a frame.

18. The solar cell module of the claim 17, wherein the cell structure has two EVA layers and a cell between the two EVA layers.

19. A manufacturing method of a solar cell module comprising:
a step of hot pressing a protecting plate, a cell structure and a supporting structure.

20. The manufacturing method of the claim 19 further comprising a step of folding a bottom plate of the supporting structure after hot pressing.
